(19) United States
(12) Patent Application Publication
(10) Pub. No.: US 2024/0250095 A1
(43) Pub. Date: Jul. 25, 2024

(54) ARRAY SUBSTRATES AND METHODS FOR MANUFACTURING THE SAME, DISPLAY PANELS AND DISPLAY DEVICES

(71) Applicants: Hefei BOE Display Technology Co., Ltd., Hefei, Anhui (CN); BOE Technology Group Co., Ltd., Beijing (CN)

(72) Inventors: Zexu LIU, Beijing (CN); Jincheng GAO, Beijing (CN); Haijiao QIAN, Beijing (CN); Lixing ZHAO, Beijing (CN); Liang CHEN, Beijing (CN); Tao WANG, Beijing (CN); Dengpan ZHU, Beijing (CN); Wentao LU, Beijing (CN); Guanyong ZHANG, Beijing (CN)

(21) Appl. No.: 17/914,946

(22) PCT Filed: Oct. 27, 2021
(86) PCT No.: PCT/CN2021/126732

§ 371 Date: Sep. 27, 2022

(30) Foreign Application Priority Data
Mar. 22, 2021 (CN) 202110302680.2

(51) Int. Cl. H01L 27/12

(52) U.S. Cl. CPC H01L 27/1244; H01L 27/1288; H01L 27/1248

(57) ABSTRACT

The present disclosure provides an array substrate and a method for manufacturing the same, a display panel and a display device. The array substrate includes along a thickness direction: a base substrate; a gate line fixing portion and a common electrode, materials of the gate line fixing portion and the common electrode are identical conductive materials and the gate line fixing portion and the common electrode are located in the same structural layer; a gate line arranged on the gate line fixing portion, and a common electrode line arranged on the common electrode, the gate line fixing portion is used for fixing the gate line to the base substrate. The display panel includes the array substrate. The display device includes the display panel. The manufacturing method is used to manufacture the array substrate.

### CROSS-REFERENCE TO RELATED APPLICATIONS

This application is a national stage of international PCT Application No. PCT/CN2021/126732 filed on Oct. 27, 2021, the entire contents of which are incorporated herein by reference.

This disclosure claims priority to Chinese patent application No. 202110302680.2 entitled “ARRAY SUBSTRATES AND METHODS FOR MANUFACTURING THE SAME, DISPLAY PANELS AND DISPLAY DEVICES”, filed with the Chinese Patent Office on Mar. 22, 2021, the entire contents of which are incorporated herein by reference.

### TECHNICAL FIELD

The present disclosure relates to the field of display technology, and in particular to array substrates and methods for manufacturing the same, display panels and display devices.

### BACKGROUND

With the rapid development of peoples lives, consumers have higher demands for picture quality of display products, and various products with a high resolution as 8K and a high refresh rate as 120 Hz have come into being. Due to the demand of high-end products for a charging rate, it is expected to further improve a yield rate related to a gate electrode and performance to meet demands of current products. While, since copper (Cu) materials are currently mostly used for gate lines, in actual production processes, molybdenum lithium (MoNb) is used to increase the adhesion between Cu and glass, so as to prevent a Cu film from falling off during coating.

At present, a cost of a MoNb target is relatively high, and fine particles may be generated during the coating. As shown in FIG. 1, such fine particle P often causes circuit failure in an array substrate, resulting in short circuit failure between a gate electrode and a source electrode or short circuit failure between a source electrode and a common electrode line, which affects the product yield rate. With a gate semipermeable film exposure process (Half-Tone), a film can be formed without using the MoNb target during the gate film formation. However, the process is difficult to be applied to thin bezel products due to product yield rate problems. Therefore, for such thin bezel products, the gate semipermeable film exposure process cannot be used to avoid defects related to the fine particles caused by the MoNb target.

The gate semipermeable film exposure process (Half-Tone) is etched twice, so a difference between a final gate size and an exposed gate size is at a level of 3.6 μm to 4.2 μm (micrometer). For an ordinary exposure process, the difference is generally at a level of 1.2 μm to 1.5 μm level. As shown in FIG. 2, as two etch processes are needed in the gate semipermeable film exposure process, excess portions W in a range of 1.1 μm to 1.5 μm may appear on both sides of gate 60′, which results in a large size difference. An overall size of peripheral lines for a display screen is often designed to be within a range from 12 μm to 13.4 μm. As customers' demands for products having a slim bezel design, the size of peripheral lines is generally expected to be designed at a level of 11.4 μm. For the gate semipermeable film exposure process, the difference between the final gate size and the exposed gate size is too large, which often leads to a high incidence of peripheral line breakage defects, as well as the yield rate failing to meet production demands and the customer supply. In view of such situations, only the ordinary exposure process can be used.

Therefore, under the existing process conditions, how to reduce the short circuit failure between the gate electrode and the source electrode and the short circuit failure between the source electrode and the common electrode line is a technical problem to be solved urgently in the field.

### SUMMARY

In the present disclosure, an array substrate and a method for manufacturing the same, a display panel and a display device are provided, which can reduce the occurrence of a short circuit failure between a gate electrode and a source electrode and a short circuit failure between a source electrode and a common electrode line, thereby improving the product yield rate.

In a first aspect of embodiments of the present disclosure, there is provided an array substrate. The array substrate along a thickness direction includes:
a base substrate;
a gate line fixing portion and a common electrode which are arranged on the base substrate and insulated from each other, where materials of the gate line fixing portion and the common electrode are identical conductive materials, and the gate line fixing portion and the common electrode are located in one structural layer;
a gate line arranged on the gate line fixing portion and a common electrode line arranged on the common electrode, where the gate line fixing portion fixes the gate line to the base substrate, materials of the gate line and the common electrode line are identical materials, and the gate line and the common electrode line are located in one structural layer and are arranged to be insulated from each other;
a first insulating layer located on the base substrate, where the first insulating layer covers the gate line, the common electrode line and the common electrode; and
a second insulating layer located on the first insulating layer, and a pixel electrode located on the second insulating layer.

Optionally, materials of the gate line fixing portion and the common electrode are identical metal materials.

Optionally, materials of the gate line fixing portion and the common electrode are identical transparent conductive materials.

Optionally, an orthographic projection of the gate line fixing portion on the base substrate coincide exactly with an orthographic projection of the gate line on the base substrate.

Optionally, materials of both the gate line fixing portion and the common electrode include Indium Tin Oxide (ITO); materials of both the gate line and the common electrode line include copper; and a material of the pixel electrode includes a transparent conductive material, and the material of the pixel electrode includes ITO.

Optionally, thicknesses of the common electrode and the gate line fixing portion are identical, and the thicknesses of both the common electrode and the gate line fixing portion are 0.03 μm-0.07 μm;
thicknesses of the common electrode line and the gate line are identical, and the thicknesses of both the common electrode line and the gate line are 0.35 μm-0.60 μm;
a thickness of the first insulating layer is 0.35 μm-0.45 μm;
a thickness of the second insulating layer is 0.55 μm-0.65 μm; and
a thickness of the pixel electrode is 0.03 μm-0.07 μm.

Optionally, both the gate line and the common electrode line are of a single-layer metal structure.

Optionally, the array substrate includes a plurality of pixel units, each of the plurality of pixel units includes a thin film transistor, the pixel electrode, the common electrode and the common electrode line, the thin film transistor includes a gate electrode, a source electrode and a drain electrode, and the gate electrode is a partial structure of the gate line. In a second aspect of embodiments of the present disclosure, there is provided a display panel including the array substrate described above.

In a third aspect of embodiments of the present disclosure, there is provided a display device including the display panel described above.

In a fourth aspect of embodiments of the present disclosure, there is provided a method of manufacturing an array substrate for manufacturing the array substrate described above. The method of manufacturing the array substrate includes following steps.
forming a first conductive layer on the base substrate;
forming a second conductive layer on the first conductive layer;
patterning the second conductive layer to form the gate line and the common electrode line, where the common electrode line and the gate line are arranged to be insulated from each other;
patterning the first conductive layer to form the common electrode and the gate line fixing portion located underneath the gate line, where the gate line fixing portion fixes the gate line to the base substrate, a part of the common electrode is located under the common electrode line, and the common electrode and the gate line fixing portion are arranged to be insulated from each other;
forming the first insulating layer on the base substrate, where the first insulating layer covers the gate line, the common electrode line and the common electrode;
forming the second insulating layer on the first insulating layer; and
forming the pixel electrode on the second insulating layer.

Optionally, a material of the first conductive layer includes a metal material.

Optionally, a material of the first conductive layer includes a transparent conductive material.

Optionally, an orthographic projection of the gate line fixing portion on the base substrate coincide exactly with an orthographic projection of the gate line on the base substrate.

Optionally, for forming the first conductive layer on the base substrate, the first conductive layer is formed by rotating a target.

Optionally, a structure of the second conductive layer is a single-layer metal structure, and for forming the second conductive layer on the first conductive layer, the second conductive layer is formed by using a multi-cavity coating device, and each cavity forms a layer structure with a partial thickness of the single-layer metal structure.

Optionally, for patterning the second conductive layer to form the gate line and the common electrode line, etching is performed by using etchant with a high selectivity for the second conductive layer; and/or
for patterning the first conductive layer to form the common electrode and the gate line fixing portion located underneath the gate line, etching is performed by using etchant with a high selectivity for the first conductive layer.

Optionally, the gate line and the common electrode line are formed by using an identical mask; and the common electrode and the gate line fixing portion located underneath the gate line are formed by patterning the first conductive layer with an identical mask.

Optionally, for forming the first insulating layer on the base substrate, the first insulating layer is formed through a Plasma Enhanced Chemical Vapor Deposition (PECVD) process, and a temperature of the PECVD process is 350° C.-370° C.; and
a crystallization process for the common electrode and the gate line fixing portion is completed in the process of forming the first insulating layer through the PECVD process.

In the array substrates, display panels and display devices of the present disclosure, the gate line is fixed on the base substrate through the gate line fixing portion that has the same conductive material as the common electrode. Therefore, the gate line fixing portion having the same conductive material as the common electrode can be used to replace a MoNb material layer for increasing the adhesion between the gate line and the base substrate. Thus, the occurrence of short circuit failure between the gate electrode and the source electrode, and short circuit failure between the source electrode and the common electrode line can be alleviated, thereby improving the product yield rate.

For the methods of manufacturing an array substrate in the present disclosure, on one hand, the gate line is fixed to the base substrate through the gate line fixing portion that has the same conductive material as the common electrode. Therefore, the gate line fixing portion having the same conductive material as the common electrode can be used to replace a MoNb material layer for increasing the adhesion between the gate line and the base substrate. Thus, the occurrence of short circuit failure between the gate electrode and the source electrode, and short circuit failure between the source electrode and the common electrode line can be alleviated, thereby improving the product yield rate.

On the other hand, an original manufacturing process flow in the prior art can include, when a first conductive layer is formed, the first conductive layer is patterned to form a common electrode firstly; then a second conductive layer is formed, and the second conductive layer is patterned to form a gate line and a common electrode line. However, in the present embodiments, the first conductive layer and the second conductive layer can be formed in sequence, the second conductive layer is patterned to form a gate line and a common electrode line, and the first conductive layer is patterned to form a common electrode and a gate line fixing portion. Therefore, for an original device, by simply changing the process without replacing a mask with a new one, the use of the MoNb target can be reduced, thereby reducing the producing cost of products.

### BRIEF DESCRIPTION OF THE DRAWINGS

FIG. 1 is a partial actual micrograph of an array substrate in the prior art.

FIG. 2 is a schematic diagram illustrating a partial cross-sectional structure of an array substrate in the prior art.

FIG. 3 is a schematic top view illustrating a partial structure of an array substrate according to an exemplary embodiment of the present disclosure.

FIG. 4 is a cross-sectional view along a direction A-A in FIG. 3.

FIG. 5 is a cross-sectional view along a direction B-B′ in FIG. 3.

FIG. 6 is a flowchart illustrating a method of manufacturing an array substrate according to an exemplary embodiment of the present disclosure.

FIGS. 7 to 10 are process step diagrams for a method of manufacturing an array substrate according to an exemplary embodiment of the present disclosure.

FIG. 11 is a partial actual micrograph of an array substrate according to an exemplary embodiment of the present disclosure.

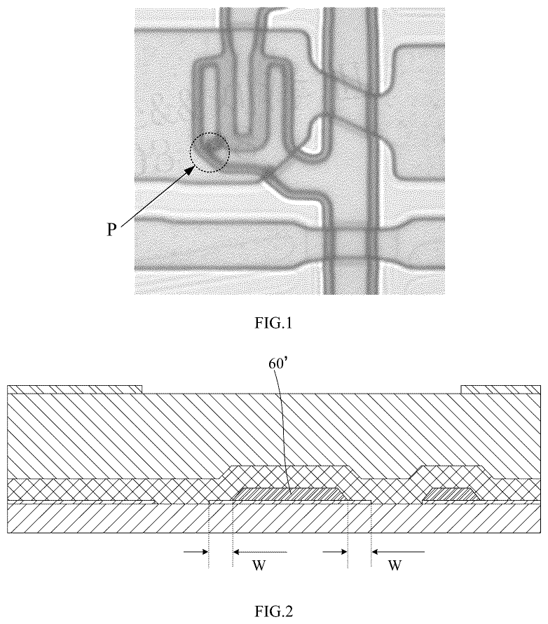

### DETAILED DESCRIPTION OF THE EMBODIMENTS

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses consistent with some aspects of the present disclosure as detailed in the appended claims.

The terms used in the present disclosure are for the purpose of describing particular embodiments only, and are not intended to limit the present disclosure. Unless otherwise defined, technical or scientific terms used in this disclosure should have ordinary meaning as understood by one of ordinary skill in the art to which the disclosure belongs. Words such as “one”, “a” or “an” used in the specification and claims of the present disclosure do not represent a quantity limit, but represent that there is at least one. Words such as “including” or “including” mean that an element or an item appearing before “including” or “including” covers elements or items and their equivalents listed after “including” or “including”, without excluding other elements or items. Words such as “connect” or “connected with each other” are not limited to physical or mechanical connections, and may include electrical connections, whether direct or indirect. “Plurality”, “multiple” or “several” means two or more. Terms determined by “a/an”, “the” and “said” in their singular forms in the present specification and the appended claims are also intended to include plural forms unless clearly indicated otherwise in the context. It should also be understood that the term “and/or” as used herein refers to and includes any or all possible combinations of one or more associated listed items.

In the present embodiments, an array substrate and a method for manufacturing the same, a display panel and a display device are provided.

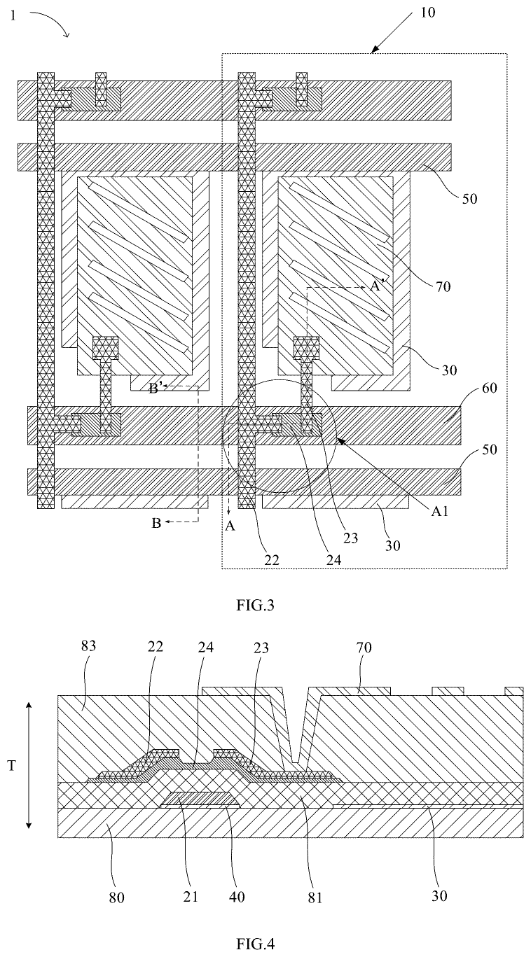

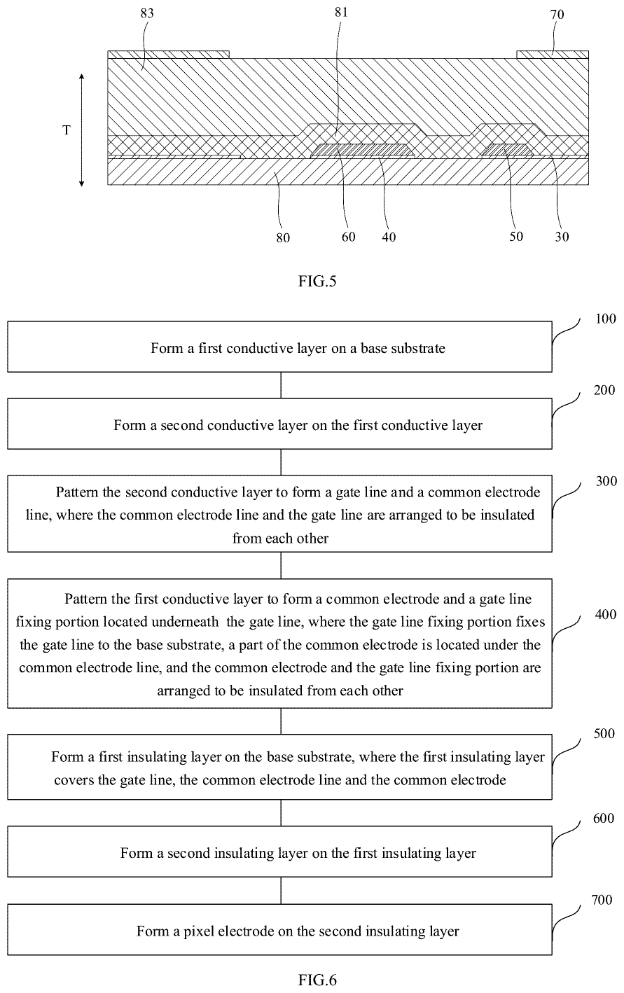

As shown in the FIG. 3 to FIG. 5, an array substrate 1 may include a plurality of pixel units 10, and each pixel unit 10 may include a thin film transistor, a pixel electrode 70, a common electrode 30 and a common electrode line 50. The thin film transistor may include a gate electrode 21, a source electrode 23 and a drain electrode 22, and the gate electrode 21 is a part of a gate line 60. The thin film transistor may further include an active layer 24, and both the source electrode 23 and the drain electrode 22 can be located on the active layer 24. The source electrode 23 can be connected to the pixel electrode 70, and the source electrode 23 and the drain electrode 22 can switch with each other. The gate electrode 21 and the source electrode 23 can be powered up at the same time, so that the active layer 24 can become conductive. When the active layer 24 is conductive, the source electrode 23 can supply electricity to the drain electrode 22 for completing a charging process for pixels through the drain electrode 22. In FIG. 3. A1 represents a component region of the thin film transistor, and a part of the gate line 60 within the region A1 constitutes the gate electrode 21 of the thin film transistor, that is, the gate electrode 21 is a partial structure of the gate line 60.

The array substrate 1, along a thickness direction T, may include, a base substrate 80; a gate line fixing portion 40 and a common electrode 30 which are arranged on the base substrate 80 and insulated from each other, where materials of the gate line fixing portion 40 and the common electrode 30 can be identical conductive materials, and the gate line fixing portion 40 and the common electrode 30 can be located in the same structural layer; a gate line 60 arranged on the gate line fixing portion 40, and a common electrode line 50 arranged on the common electrode 30, where the gate line fixing portion 40 can fix the gate line 60 to the base substrate 80, materials of the gate line 60) and the common electrode line 50 can be identical materials and the gate line 60 and the common electrode line 50 can be located in the same structural layer and be arranged to be insulated from each other; a first insulating layer 81 located on the base substrate 80, where the first insulating layer 81 can cover the gate line 60, the common electrode line 50) and the common electrode 30; an active layer 24 located on the first insulating layer 81, and the source electrode 23 and the drain electrode 22 which are located on the active layer 24; a second insulating layer 83 located on the first insulating layer 81, where the second insulating layer 83 can cover the active layer 24, the source electrode 23 and the drain electrode 22; and a pixel electrode 70 located on the second insulating layer 83. The first insulating layer 81 can be an insulating layer of the gate electrode 21, and the second insulating layer 83 can be a passivation layer.

In this way, with the gate line fixing portion 40 using the same conductive material as the common electrode 30, the gate line 60 is fixed to the base substrate 80, so that a MoNb material layer can be replaced with the gate line fixing portion 40 to increase the adhesion between the gate line 60 and the base substrate 80. Therefore, the occurrence of short circuit failure between the gate electrode 21 and the source electrode 23 or short circuit failure between the source electrode 23 and the common electrode line 50 can be alleviated, thereby improving the product yield rate.

An orthographic projection of the gate line fixing portion 40 on the base substrate 80) can coincide exactly with an orthographic projection of the gate line 60 on the base substrate 80, so as to ensure that the gate line fixing portion 40 does not affect a size of the gate line 60, and realize a beneficial effect of precisely controlling the size of the gate line 60. Furthermore, it can be ensured that a gate line fixing portion 40 can be provided underneath each gate line 60. While providing a fixation for the gate line 60, the gate line fixing portion 40 can also provide a complete support for the gate line 60, without arising a problem in which cracks occur at the first insulating layer's bottom due to the gate line fixing portion 40 not existing at some lower positions, especially at edges, of the gate line 60.

In the present embodiment, materials of the gate line fixing portion 40 and the common electrode 30 are identical transparent conductive materials. Specifically, materials of the gate line fixing portion 40 and the common electrode 30 may be, but are not limited to, Indium Tin Oxide, may also be a transparent conductive material such as graphene. Materials of the gate line 60) and the common electrode line 50 can generally use metallic materials (e.g., copper, aluminum, etc.). A material of the pixel electrode 70 may be a transparent conductive material. Specifically, the material of the pixel electrode 70 may be, but is not limited to, Indium Tin Oxide, may also be Indium Gallium Zinc Oxide, Indium Zinc Oxide, Indium Gallium Tin Oxide and the like.

In other embodiments, the materials of the gate line fixing portion 40 and the common electrode 30 may also be, but are not limited to, identical mental materials, may also be other materials that can conduct electricity.

Optionally, thicknesses of the common electrode 30 and the gate line fixing portion 40 may be identical, and the thicknesses of both the common electrode 30 and the gate line fixing portion 40 may be 0.03 μm-0.07 μm. Preferably, the thicknesses of both the gate line fixing portion 40 and the common electrode 30 can be 0.04 μm.

Thicknesses of the common electrode line 50 and the gate line 60 may be identical, and the thicknesses of both the common electrode line 50 and the gate line 60 may be 0.35 μm-0.60 μm. Combining the transmittance and the manufacturing cost, the thicknesses of both the common electrode line 50 and the gate line 60 can be preferably 0.45 μm.

A thickness of the first insulating layer 81 may be 0.35 μm-0.45 μm. Preferably, the thickness of the first insulating layer 81 can be 0.40 μm.

A thickness of the second insulating layer 83 may be 0.55 μm-0.65 μm. Preferably, the thickness of the second insulating layer 83 can be 0.60 μm.

A thickness of the pixel electrode 70 may be 0.03 μm-0.07 μm. Combining the transmittance and the manufacturing cost, the thickness of the pixel electrode 70 can be preferably 0.04 μm.

Both the gate line 60 and the common electrode line 50 can be of a single-layer metal structure.

The gate line fixing portion 40 and the common electrode 30 can be in the same layer structure formed by a mask. That is, the gate line fixing portion 40 and the common electrode 30 can be formed in the same process step to improve the production efficiency.

The gate line 60 and the common electrode line 50 can be in the same layer structure formed by a mask. That is, the gate line 60 and the common electrode line 50 can be formed in the same process step to improve the production efficiency.

The first insulating layer 81 can be formed through a PECVD (Plasma Enhanced Chemical Vapor Deposition) process, and a temperature of the PECVD process may be 350° ° C. to 370° C. A crystallization process for the common electrode 30 and the gate line fixing portion 40 can be completed during forming the first insulating layer 81 through the PECVD process.

This is because, in an original manufacturing process flow of the prior art, when a first conductive layer is formed, the first conductive layer is patterned to form the common electrode 30 firstly. And then, the second conductive layer is formed, and the second conductive layer is successively patterned to form the gate line 60 and the common electrode line 50. In response to completing the patterning of the first conductive layer, a crystallization process (annealing process) is further needed to reduce a resistance of the common electrode 30, and a temperature of the crystallization process is mostly 220° C. to 240° C. In contrast, in the present embodiments, a high temperature in the process of forming the first insulating layer 81 can be used to perform crystallization on the common electrode 30, thereby simplifying the process flow. That is, relative to the prior art, the present embodiments can eliminate the annealing process after patterning the first conductive layer, thereby simplifying the process flow.

The temperature of the PECVD process may be 350° C.-370° C., and preferably, the temperature of the PECVD process can be 360° C.

The present embodiment further provides display panels, which can include the above-mentioned array substrate 1.

The present embodiment further provides display devices, which can include the above-mentioned display panels.

FIG. 6 is a flowchart illustrating a method of manufacturing an array substrate proposed by the present embodiments. As shown in FIG. 6, the manufacturing methods can include the following steps.

At step 100, a first conductive layer is formed on a base substrate.

At step 200, a second conductive layer is formed on the first conductive layer.

At step 300, the second conductive layer is patterned to form a gate line and a common electrode line, where the common electrode line and the gate line are arranged to be insulated from each other.

At step 400, the first conductive layer is patterned to form a common electrode and a gate line fixing portion located underneath the gate line, where the gate line fixing portion fixes the gate line to the base substrate, a part of the common electrode is located under the common electrode line, and the common electrode and the gate line fixing portion are arranged to be insulated from each other.

At step 500, a first insulating layer is formed on the base substrate, where the first insulating layer covers the gate line, the common electrode line and the common electrode.

At step 600, a second insulating layer is formed on the first insulating layer.

At step 700, a pixel electrode is formed on the second insulating layer.

For the methods of manufacturing an array substrate in the present disclosure, on one hand, the gate line is fixed to the base substrate through the gate line fixing portion that is made of the same conductive material as the common electrode. Therefore, the gate line fixing portion with the same conductive material as the common electrode can be used to replace a MoNb material layer for increasing the adhesion between the gate line and the base substrate. Thus, the occurrence of short circuit failure between the gate electrode and the source electrode, and short circuit failure between the source electrode and the common electrode line can be alleviated, thereby improving the product yield rate.

On the other hand, an original manufacturing process flow in the prior art can include, when a first conductive layer is formed, the first conductive layer is patterned to form a common electrode firstly; then a second conductive layer is formed, and the second conductive layer is patterned to form a gate line and a common electrode line. However, in the present embodiments, the first conductive layer and the second conductive layer can be formed in sequence, the second conductive layer is patterned to form a gate line and a common electrode line, and then the first conductive layer is patterned to form a common electrode and a gate line fixing portion. Therefore, for an original device, by simply changing the process without replacing a mask with a new one, the use of the MoNb target can be reduced, thereby reducing the producing cost of products.

In addition, unlike the gate semipermeable film exposure process mentioned in the background, which needs two etchings to form a gate line, in the present embodiments, only one etching is performed while manufacturing a gate line with patterning. Therefore, excess portions beside the gate electrode would not appear, so a failure problem of an increasing parasitic capacitance related to the excess portions would not occur.

It should be further noted that, while patterning the first conductive layer, in the present embodiments, the patterned gate line is used as a mask to pattern the first conductive layer to form a gate line fixing portion located underneath the gate line.

In a case of using a manufacturing manner in which the second conductive layer is patterned after patterning the first conductive layer, a mask for forming a common electrode and a gate line fixing portion needs to be changed, thereby increasing the cost. Moreover, in a case that a changed mask is used, in a process of patterning the common electrode and the gate line fixing portion first and then patterning the gate line, due to a limitation of the alignment accuracy of an exposure process, a pattern of the gate line may be misaligned with a pattern of the gate line fixing portion by 2 μm to 3 μm, and there may be a risk of cracking at the bottom of the first insulating layer. However, in the present embodiments, the patterned gate line is used as a mask for patterning the first conductive layer to form the gate line fixing portion located underneath the gate line, so misalignment between the pattern of the gate line and the pattern of the gate line fixing portion is alleviated, and such risk can be reduced.

Specifically, as shown in FIGS. 7 to 10, the method of manufacturing an array substrate of the present embodiment can include the following.

At step 100, as shown in FIG. 7, a first conductive layer 91 can be formed on a base substrate 80, and a material of the first conductive layer 91 may be a conductive material. The first conductive layer 91 may be formed on the base substrate 80 through a process such as deposition or sputtering or the like.

Materials of the gate line fixing portion 40 and the common electrode 30 may be the same transparent conductive materials. Specifically, the materials of the gate line fixing portion 40 and the common electrode 30 may include, but are not limited to, Indium Tin Oxide, graphene or the like.

In other embodiments, the materials of the gate line fixing portion 40 and the common electrode 30 may also be, but are not limited to, the same mental materials. The materials of the gate line fixing portion 40 and the common electrode 30 may also be other materials that can conduct electricity.

Preferably, for forming the first conductive layer 91 on the base substrate 80, the first conductive layer 91 is formed by rotating a target. This is because the uniformity of the film formed by rotating the target is better.

At step 200, as shown in FIG. 8, a second conductive layer 92 can be formed on the first conductive layer 91. Through a process, for example, deposition or sputtering or the like, the second conductive layer 92 can be formed on the first conductive layer 91.

In the present embodiments, a structure of the second conductive layer 92 may be a single-layer metal structure, and for forming the second conductive layer 92 on the first conductive layer 91, a multi-cavity coating device can be used to form the second conductive layer 92 and each cavity forms a layer structure with a partial thickness of the single-layer metal structure, so as to reduce the fragment risk of the base substrate 80 and improve the product yield rate.

This is because, in the prior art, structures of the gate line and the common electrode line are multi-layer structures, that is, along a thickness direction T with a direction, from close to the base substrate to away from the base substrate, one or more MoNb metal material layers and one or more copper metal material layers stacked in sequence can be included. In other words, the second conductive layer in the prior art can include one or more MoNb metal material layers and one or more copper metal material layers. When forming the second conductive layer, the multi-cavity coating device can be used to form the second conductive layer, and the multi-cavity coating device can be generally divided into two to three cavities for coating. The second conductive layer may include one or more MoNb metal material layers, MoNb metal material layer(s) needs to occupy at least one cavity in the multi-cavity coating device for coating, and copper metal material layer(s) is coated in the remaining cavity, resulting in a large thickness of film coated by the single cavity. However, a material of the underlying base substrate is glass, and thus the base substrate may be prone to generating fragments, thereby affecting the product yield rate.

However, in the present embodiments, by setting the structure of the second conductive layer 92 to be a single-layer metal structure (e.g., copper metal), all cavities of the multi-cavity coating device can be used to coat a copper film. That is, each cavity forms a layer structure with a partial thickness of the single-layer metal structure, so that the thickness of the film layer coated by each cavity becomes thinner, so as to reduce the fragmentation risk of the base substrate 80 and improve the product yield rate.

At step 300, as shown in FIG. 9, the second conductive layer 92 is patterned to form a gate line 60 and a common electrode line 50, where the common electrode line 50 and the gate line 60 are arranged to be insulated from each other.

Specifically, the gate line 60 and the common electrode line 50 are formed by coating photoresist, exposing, developing, etching, and stripping the photoresist and other process steps.

For patterning the second conductive layer 92 to form the gate line 60 and the common electrode line 50, etching is performed by using etchant with a high selectivity for the second conductive layer 92. It should be noted that the selectivity can refer to an etch selectivity, and the etch selectivity can refer to a relative comparison of a ratio of one material's etching rate to another material's etching rate under the same etching condition. The selectivity can be defined as a ratio of an etching rate for a material being etched to an etching rate for another material. The etchant with a high selectivity for the second conductive layer 92 can refer to that, a ratio of the etchant's etching rate for a film layer to be etched (the second conductive layer 92) to the etchant's etching rate for a film layer not to be etched (the first conductive layer 91 and other film layers) is relative high.

Specifically, the high selectivity here can refer to an etching selection ratio more than 100 to 1, that is, an etching rate of a film layer to be etched is 100 times higher than an etching rate of a film layer not to be etched, so that the film layer to be etched can be etched in a targeted manner, and the influence on the film layer not to be etched can be reduced. Since the first conductive layer 91 may be exposed during etching the gate line 60 and the common electrode line 50, by etching the second conductive layer 92 with etchant having a high selectivity, the influence on the first conductive layer 91 and other film layers during the etching the second conductive layer 92 can be reduced.

In the present embodiments, the gate line 60 and the common electrode line 50 are formed by using the same mask. The mask can be the same as a mask used for patterning the second conductive layer in the manufacturing process flow using MoNb of the prior art.

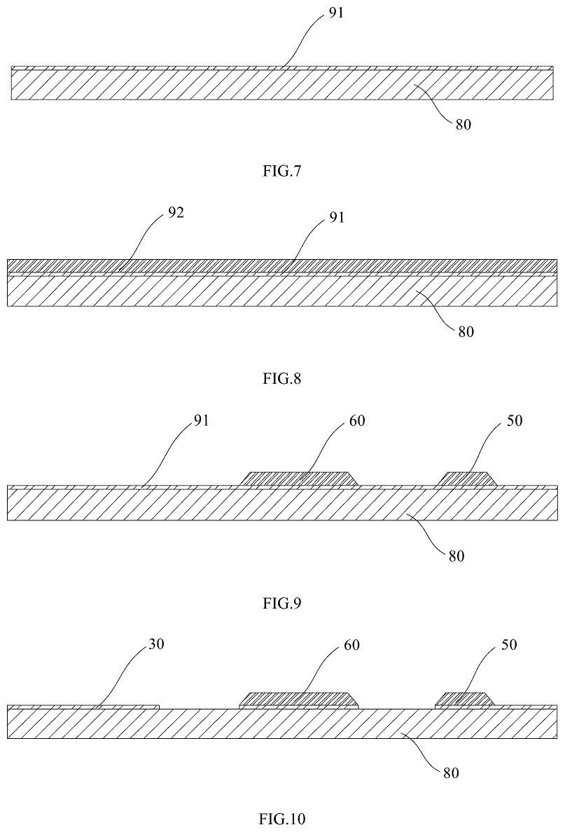

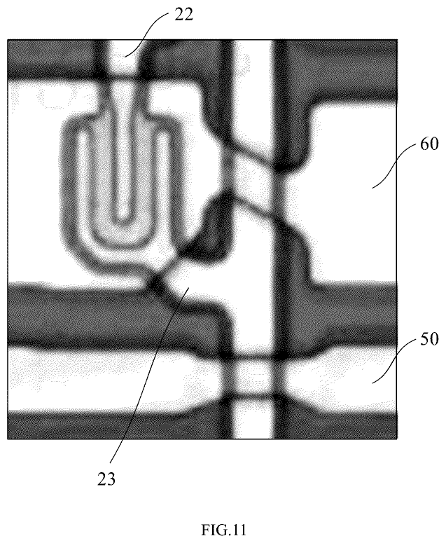

At step 400, as shown in FIG. 10, the first conductive layer 91 is patterned to form a common electrode 30 and a gate line fixing portion 40 located underneath the gate line 60. The gate line fixing portion 40 is used to fix the gate line 60 to the base substrate 80, a part of the common electrode 30 is located under the common electrode line 50, and the common electrode 30 and the gate line fixing portion 40 are arranged to be insulated from each other.

Specifically, the common electrode 30 and the gate line fixing portion 40 are formed by coating photoresist, exposing, developing, etching, and stripping the photoresist and other process steps.

For patterning the first conductive layer 91 to form the common electrode 30 and the gate line fixing portion 40 located underneath the gate line 60, etchant with a high selectivity for the first conductive layer 91 is used to perform etching. The high selectivity here may refer to a selectivity of more than 100 to 1 as well. The related concept of high selectivity has been explained above, and will not be repeated here.

By etching the first conductive layer 91 with the etchant having a high selectivity, the influence on other film layers during the etching process can be reduced.

In the present embodiments, the first conductive layer 91 is patterned by using the same mask to form the common electrode 30, and the gate line fixing portion 40 located underneath the gate line 60. The mask can be the same as a mask used for patterning the first conductive layer in the manufacturing process flow using MoNb of the prior art.

When patterning the first conductive layer 91, the gate line 60 may block the first conductive layer 91 underneath the gate line 60 itself, so as to ensure that an orthographic projection of the gate line fixing portion 40 on the base substrate 80 can coincide with an orthographic projection of the gate line 60 on the base substrate 80. It can be ensured that the gate line fixing portion 40 does not affect a size of the gate line 60, and realize a beneficial effect of precisely controlling the size of the gate line 60. Furthermore, it can be ensured that a gate line fixing portion 40 can be provided underneath each gate line 60. While providing a fixation for the gate line 60, the gate line fixing portion 40 can also provide a full support for the gate line 60, without arising a problem in which cracks occur at the first insulating layer's bottom due to the gate line fixing portion 40 not existing at some lower positions, especially at edges, of the gate line 60.

At step 500, a first insulating layer 81 is formed on the base substrate 80, and the first insulating layer 81 covers the gate line 60, the common electrode line 50 and the common electrode 30.

For forming the first insulating layer 81 on the base substrate 80, the first insulating layer 81 can be formed through a PECVD process, and a temperature of the PECVD process can be 350° C.-370° C. A crystallization process for the common electrode 30 and the gate line fixing portion 40 can be completed in the process of forming the first insulating layer 81 through the PECVD process.

As mentioned above, in an original manufacturing process flow of the prior art, when a first conductive layer 91 is formed, the first conductive layer 91 is first patterned to form the common electrode 30. And then, the second conductive layer 92 is formed, and the second conductive layer 92 is successively patterned to form the gate line 60 and the common electrode line 50. In response to completing the patterning of the first conductive layer 91, a crystallization process (annealing process) is further needed to reduce a resistance of the common electrode 30, and a temperature of the crystallization process is mostly 220° C. to 240° C. In contrast, in the present embodiments, a high temperature in the process of forming the first insulating layer 81 can be used to perform crystallization on the common electrode 30, thereby simplifying the process flow. That is, relative to the prior art, the present embodiment can eliminate the annealing process after patterning the first conductive layer, thereby simplifying the process flow.

The temperature of the PECVD process may be 350° C.-370° C., and preferably, the temperature of the PECVD process can be 360° C.

Before performing the step 600, forming an active layer 24 on the first insulating layer 81, and forming a source electrode 23 and a drain electrode 22 on the active layer 24 can be further included.

At step 600, a second insulating layer 83 can be formed on the first insulating layer 81, and the second insulating layer 83 can cover the active layer 24, the source electrode 23 and the drain electrode 22.

At step 700, a pixel electrode 70 can be formed on the second insulating layer 83, and the pixel electrode 70 can connect to the drain electrode 22 through a via.

The array substrates of the present embodiments can be obtained through the above-mentioned manufacturing methods. An actual micrograph of the array substrate 1 obtained through the above-mentioned manufacturing methods is shown in FIG. 11. As can be seen that due to avoid using the MoNb material layer, the actual micrograph of the array substrate 1 no longer has fine particles produced by the MoNb material.

For array substrates obtained by using the manufacturing methods of the present embodiments, a short circuit failure rate between the gate electrode and the source electrode and a short circuit failure rate between the source electrode and the common electrode line can be improved, which are shown specifically in the following table.

| | short circuit failure | short circuit failure |
|---|---|---|
| | rate between a gate | rate between a source |
| | electrode and a source | electrode and a common |
| Process condition | electrode | electrode line |
| Traditional process | 0.96% | 1.84% |
| condition | | |
| Process condition | 0.94% | 1.57% |
| of the present | | |
| embodiments | | |

As can be seen from the above table, the short circuit failure rate between a gate electrode and a source electrode is reduced by 0.02%, and the short circuit failure rate between a source electrode and a common electrode line is reduced by 0.27%. Therefore, the short circuit failure rate between a gate electrode and a source electrode and the short circuit failure rate between a source electrode and a common electrode line have been improved.

The manufacturing methods in the present embodiments can be applied to OLED (Organic Light-Emitting Diode) manufacturing and other production lines that need manufacturing an exposure mask with photoresist.

The above are only preferred embodiments of the present disclosure, and are not intended to limit the present disclosure. Without departing from the spirit and principle of the present disclosure, any revisions, equivalent replacements, improvements, etc. made should fall within the protection scope of the present disclosure.

1. An array substrate, along a thickness direction, comprises:
a base substrate;
a gate line fixing portion and a common electrode which are arranged on the base substrate and insulated from each other, wherein materials of the gate line fixing portion and the common electrode are identical conductive materials, and the gate line fixing portion and the common electrode are located in one structural layer;
a gate line arranged on the gate line fixing portion and a common electrode line arranged on the common electrode, wherein the gate line fixing portion fixes the gate line to the base substrate, materials of the gate line and the common electrode line are identical materials, and the gate line and the common electrode line are located in one structural layer and are arranged to be insulated from each other;
a first insulating layer located on the base substrate, wherein the first insulating layer covers the gate line, the common electrode line and the common electrode; and
a second insulating layer located on the first insulating layer, and a pixel electrode located on the second insulating layer.

2. The array substrate of claim 1, wherein materials of the gate line fixing portion and the common electrode are identical metal materials.

3. The array substrate of claim 1, wherein materials of the gate line fixing portion and the common electrode are identical transparent conductive materials.

4. The array substrate of claim 1, wherein an orthographic projection of the gate line fixing portion on the base substrate coincide exactly with an orthographic projection of the gate line on the base substrate.

5. The array substrate of claim 1, wherein
materials of both the gate line fixing portion and the common electrode comprise Indium Tin Oxide (ITO);
materials of both the gate line and the common electrode line comprise copper; and
a material of the pixel electrode comprises a transparent conductive material, wherein the transparent conductive material comprises ITO.

6. The array substrate of claim 1, wherein,
thicknesses of the common electrode and the gate line fixing portion are identical, and the thicknesses of both the common electrode and the gate line fixing portion are 0.03 μm-0.07 μm;
thicknesses of the common electrode line and the gate line are identical, and the thicknesses of both the common electrode line and the gate line are 0.35 μm-0.60 μm;
a thickness of the first insulating layer is 0.35 μm-0.45 μm;
a thickness of the second insulating layer is 0.55 μm-0.65 μm; and
a thickness of the pixel electrode is 0.03 μm-0.07 μm.

7. The array substrate of claim 1, wherein both the gate line and the common electrode line are of a single-layer metal structure.

8. The array substrate of claim 1, wherein the array substrate comprises a plurality of pixel units, each of the plurality of pixel units comprises a thin film transistor, the pixel electrode, the common electrode and the common electrode line, the thin film transistor comprises a gate electrode, a source electrode and a drain electrode, and the gate electrode is a part of the gate line.

9. A display panel, comprising the array substrate according to claim 1.

10. A display device, comprising the display panel according to claim 9.

11. A method of manufacturing an array substrate, for manufacturing the array substrate according to claim 1, the method of manufacturing the array substrate comprising:
forming a first conductive layer on the base substrate;
forming a second conductive layer on the first conductive layer;
patterning the second conductive layer to form the gate line and the common electrode line, wherein the common electrode line and the gate line are arranged to be insulated from each other;
patterning the first conductive layer to form the common electrode and the gate line fixing portion located underneath the gate line, wherein the gate line fixing portion fixes the gate line to the base substrate, a part of the common electrode is located under the common electrode line, and the common electrode and the gate line fixing portion are arranged to be insulated from each other;
forming the first insulating layer on the base substrate, wherein the first insulating layer covers the gate line, the common electrode line and the common electrode;
forming the second insulating layer on the first insulating layer; and
forming the pixel electrode on the second insulating layer.

12. The method of manufacturing the array substrate according to claim 11, wherein a material of the first conductive layer comprises a metal material.

13. The method of manufacturing the array substrate according to claim 11, wherein a material of the first conductive layer comprises a transparent conductive material.

14. The method of manufacturing the array substrate according to claim 11, wherein an orthographic projection of the gate line fixing portion on the base substrate coincide exactly with an orthographic projection of the gate line on the base substrate.

15. The method of manufacturing the array substrate according to claim 11, wherein for forming the first conductive layer on the base substrate, the first conductive layer is formed by rotating a target.

16. The method of manufacturing the array substrate according to claim 11, wherein a structure of the second conductive layer is a single-layer metal structure, and for forming the second conductive layer on the first conductive layer, the second conductive layer is formed by using a multi-cavity coating device, and each cavity forms a layer structure with a partial thickness of the single-layer metal structure.

17. The method of manufacturing the array substrate according to claim 11, comprises at least one of:
for patterning the second conductive layer to form the gate line and the common electrode line, etching is performed by using etchant with a high selectivity for the second conductive layer; or
for patterning the first conductive layer to form the common electrode and the gate line fixing portion located underneath the gate line, etching is performed by using etchant with a high selectivity for the first conductive layer.

18. The method of manufacturing the array substrate according to claim 11, wherein
the gate line and the common electrode line are formed by using an identical mask; and
the common electrode and the gate line fixing portion located underneath the gate line are formed by patterning the first conductive layer with an identical mask.

19. The method of manufacturing the array substrate according to claim 11, wherein
for forming the first insulating layer on the base substrate, the first insulating layer is formed through a Plasma Enhanced Chemical Vapor Deposition (PECVD) process, and a temperature of the PECVD process is 350° ° C.-370° C.; and
a crystallization process for the common electrode and the gate line fixing portion is completed in the process of forming the first insulating layer through the PECVD process.
